(19) United States
(12) Patent Application Publication
(10) Pub. No.: US 2025/0212361 A1
(43) Pub. Date: Jun. 26, 2025

(54) HOT-SWAPPABLE LIQUID-COOLED SOLID STATE DRIVE

(71) Applicant: Microsoft Technology Licensing, LLC, Redmond, WA (US)

(72) Inventors: Kathryn OSEEN-SENDA, Seattle, WA (US); Oscar FARIAS MOGUEL, Seattle, WA (US); Dennis TRIEU, Redmond, WA (US)

(73) Assignee: Microsoft Technology Licensing, LLC, Redmond, WA (US)

(21) Appl. No.: 18/394,153

(22) Filed: Dec. 22, 2023

(51) Int. Cl. H05K 7/20; G06F 1/18; G06F 1/20; H05K 7/14

(52) U.S. Cl. CPC H05K 7/20254; G06F 1/183; G06F 1/20; H05K 7/1402; H05K 7/20454; H05K 7/20636

(57) ABSTRACT

Liquid-cooled coldplates are mounted to racks receiving solid state drives (SSDs) in an electronic component rack. The SSDs have heat spreaders with externally exposed surfaces that are thermally coupled to the coldplates using dry-contact interfaces. The SSD heat spreaders and rack-mounted coldplates provide a thermal path from the heat-producing semiconductors inside the SSD to a fluid distribution system in the rack that is operatively coupled to a liquid-cooling system. The SSDs are slideably mounted in the racks to support easy “hot-swapping.” A technician slides an SSD into the rack racks and uses a finger-operated mechanism in the SSD to simultaneously seat SSD power and data connectors to mating connectors in the rack and place the coldplate in intimate thermal contact with the SSD heat spreader.

### BACKGROUND

Computing devices generate heat as a byproduct of computational workloads. The heat is removed from the devices to enable processing to continue without incurring damage to constituent electronic components such as semiconductors. A coldplate receives heat from the electronic components to efficiently remove heat from the computing device and dissipate it to a surrounding environment.

### SUMMARY

A liquid-cooling assembly for solid state drives (SSDs) includes rack-mounted liquid-cooled coldplates that are placed in intimate thermal contact with heat spreaders on the SSDs using a dry-contact interface when the SSDs are mounted in an electronic equipment rack. A coldplate is provided in each SSD-receiving slot in the rack so that individual SSDs can be removed and replaced in “hot swapping” scenarios. The dry-contact interface between the SSD heat spreader and coldplate ensures that the SSD can be readily hot-swapped without affecting the cooling of the other SSDs in the rack.

The heat spreader in an SSD is in thermal contact with heat-producing semiconductors in the SSD. The heat spreader includes an external thermal interface in contact with mating surfaces of the coldplate to create a thermal path from the semiconductors to a liquid-cooling system. The mating surfaces of the coldplate include a dry-contact thermal interface material (TIM) to enhance the heat transfer from the SSD heat spreader.

The SSD includes a user-operable latching mechanism that functions to push against a fixed feature of the rack slot. As the SSD is slid into place, a technician manipulates the latch to firmly seat the SSD's power and data connector into a mating connector in the rack to ensure good electrical continuity while fixedly locating the SSD in position. When the SSD is seated, the coldplate is in position to contact the SSD heat spreader through the dry-contact interface to ensure effective thermal performance of the SSD using liquid-cooling.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. Furthermore, the claimed subject matter is not limited to implementations that solve any or all disadvantages noted in any part of this disclosure.

### DESCRIPTION OF THE DRAWINGS

FIGS. 1-4 show respective pictorial front, side, top, and three-quarter views of an illustrative solid state drive (SSD) configured for air-cooling;

FIG. 5 shows an illustrative arrangement of rack-mounted SSDs;

FIGS. 6-8 show various illustrative spaces provided in an electronic equipment rack for rack-mounting an SSD;

FIGS. 9-12 show an illustrative latching mechanism in an SSD for installing an SSD in an electronic equipment rack;

FIGS. 13 and 14 show respective side and top views of internal active components of an SSD;

FIG. 15 is a front view of an illustrative heat spreader assembly for an SSD;

FIG. 16 is a front partially-sectional view of an illustrative heat spreader when assembled to the internal active components of an SSD;

FIGS. 17-20 are pictorial front, side, top, and three-quarter views of an illustrative SSD configured for liquid-cooling;

FIGS. 21 and 22 show respective side and top views of an illustrative multi-segment heat spreader;

FIGS. 23 and 24 show respective front and three-quarter views of an illustrative electronic equipment rack with rack-mounted SSDs and components such as computer servers;

FIG. 25 is a simplified schematic view of an illustrative electronic equipment rack having a liquid-cooling distribution system that interfaces with a liquid-cooling system;

FIGS. 26 and 28 show respective side and three-quarter views of a first illustrative coldplate configured for use in an electronic equipment rack to provide liquid-cooling for an SSD;

FIG. 27 shows an illustrative dry break connector and fluid delivery hose;

FIG. 29 shows front views of an illustrative coldplate;

FIGS. 30-32 are detailed views of an illustrative coldplate;

FIGS. 33-36 show side views of an illustrative coldplate that is hingedly mounted in an electronic equipment rack;

FIGS. 37 and 38 show side views of an illustrative coldplate that is hingedly mounted in an electronic equipment rack and has a catch mechanism that is operable to hold the coldplate in an open position providing clearance to an SSD;

FIGS. 39 and 40 show side views of an illustrative coldplate that is mounted in an electronic equipment rack and has a mechanism for parallel movement of the coldplate relative to an SSD;

FIGS. 41 and 42 show respective side and three-quarter views of an illustrative SSD having a mechanism for latching and unlatching a coldplate to the SSD;

FIGS. 43 and 44 show an illustrative latching mechanism in an SSD for latching and unlatching a coldplate to the SSD;

FIGS. 45-49 show a cam on an SSD interfacing with a coldplate at various points of travel as the SSD is slideably installed in an electronic equipment rack;

FIGS. 50 and 51 show respective three-quarter and front views of a second illustrative liquid-cooled coldplate that is doubled-sided and configured for use in an electronic equipment rack to provide liquid-cooling for an SSD;

FIG. 52 is a front view of an illustrative embodiment of a triple-sided liquid-cooled coldplate;

FIGS. 53 and 54 show respective front and top views of illustrative hinged movements of a double-sided coldplate with respect to an SSD during installation of the SSD in an electronic equipment rack;

FIGS. 55 and 56 show respective front and top views of illustrative parallel movements of a double-sided coldplate with respect to an SSD during installation of the SSD in an electronic equipment rack; and

FIGS. 57 and 58 show respective front and top views of alternative illustrative movements of a triple-sided coldplate with respect to an SSD during installation of the SSD in an electronic equipment rack.

Like reference numerals indicate like elements in the drawings. Elements are not drawn to scale in the drawings.

### DETAILED DESCRIPTION

Solid state drives (SSDs) have historically not been liquid-cooled because air-cooling typically provides satisfactory performance. However, as semiconductors increase in geometry and total power increases, the higher heat flux that is caused makes computing devices more difficult to cool. Operators of large datacenters are increasingly moving to all liquid-cooling and have an interest in applying liquid-cooling to SSDs to gain economies of scale while avoiding the logistical complexities in simultaneously managing both air-and liquid-cooling paradigms in hybrid deployments.

The present hot-swappable liquid-cooled SSDs provide highly effective thermal management for the SSDs using compact components to enable increased SSD packing density within equipment racks. The utilization of dry-contact interfaces between the SSDs and the liquid-cooling components not only provides ease of ongoing operations such as hot-swapping, but is also readily integrated into existing liquid-cooling systems.

In a first illustrative embodiment, a liquid-cooled coldplate is configured to thermally interface with a top-mounted externally-exposed heat spreader bar that is incorporated into a heat spreader system in an SSD. In a second illustrative embodiment, a liquid-cooled coldplate is configured to thermally interface with an SSD heat spreader system over broad area surfaces.

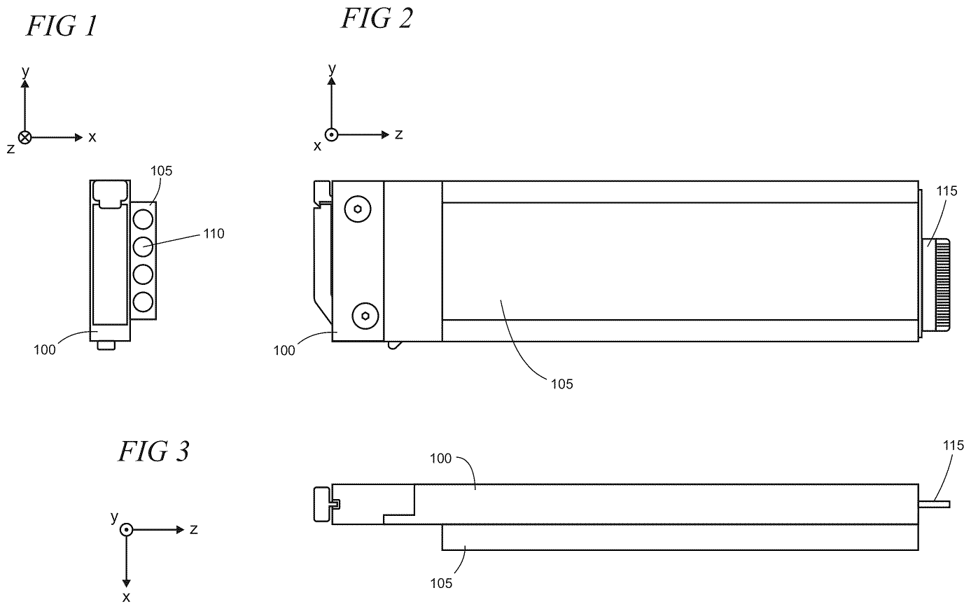

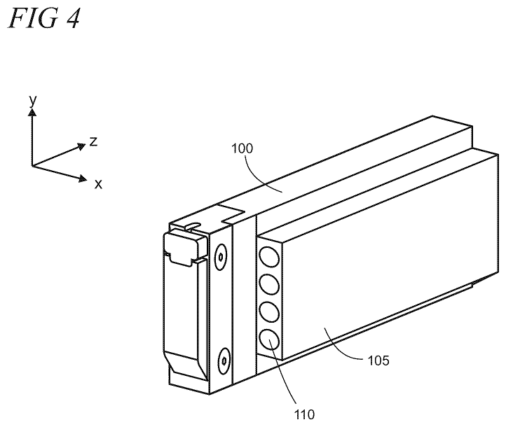

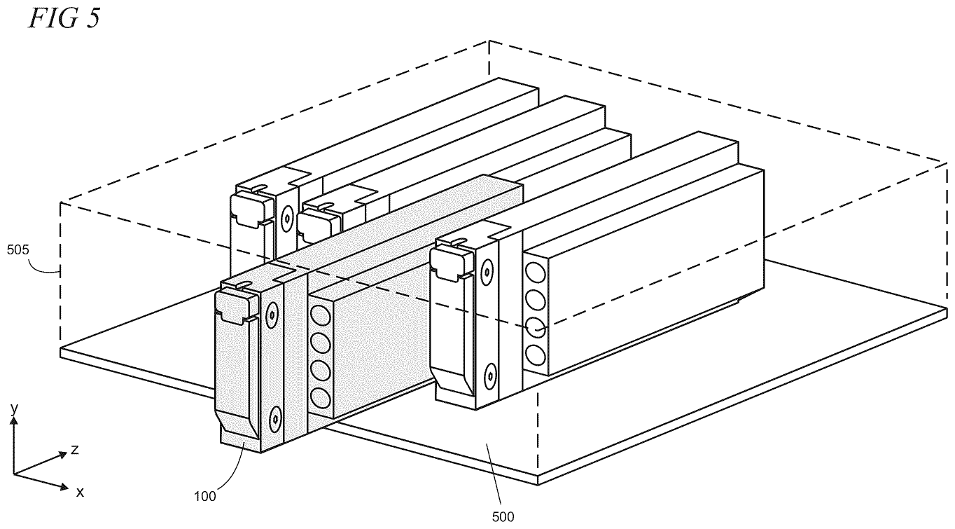

Turning now to the drawings, FIGS. 1-4 show respective pictorial front, side, top, and three-quarter views of an illustrative SSD 100 configured for air-cooling. The SSD has an E1.S form factor as described by the EDSFF (Enterprise and Datacenter Standard Form Factor). The SSD includes integrated external air-cooling fins 105 having air holes 110 that facilitate air movement across the fins. The SSD includes a connector 115 that provides electrical connections for power and data circuits.

SSDs are typically mounted in an electronic equipment chassis in typical datacenter applications. Chassis are alternatively commonly referred to as “racks” or “bays” and typically configured using standardized sizing, for example, a 19 in. (482.6 mm) width between mounting rails, as defined by the Electronic Industries Alliance (EIA). A computer server rack is commonly 42 to 48U tall (1U is equal to 44.5 mm (1.75 in.)) and can have varying depth. Another rack architecture that is in common use in datacenters and adaptable to use the present principles is the Open Rack described by the Open Computer Project. Open Rack units are commonly referred to as OpenU or OU have 21 in. (538 mm) rail spacing with a 1OU height of 48 mm (1.89 inches).

FIG. 5 shows an illustrative arrangement of rack-mounted SSDs 100. A portion of a rack 500 is shown supporting a number of air-cooled SSDs. The SSDs are slideably installed from the front of the rack within a 1U rack space (indicated by reference numeral 505). The SSDs fit into component-receiving spaces within the rack in which each space (commonly termed a “slot”) has a corresponding mating connector to interface with connector 115 (FIG. 1). To facilitate hot-swapping, SSDs are typically mounted in the rack in a manner which does not use fasteners that require tools.

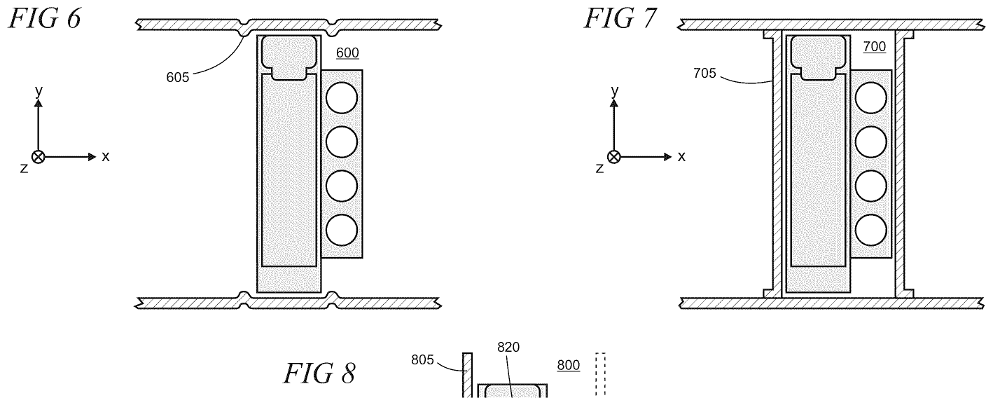

The slot implementation can vary by the type of component being rack-mounted, rack manufacturer, and other factors. FIGS. 6-8 show various illustrative slots provided in an electronic equipment rack for rack-mounting an SSD 100. For example, FIG. 6 shows corrugations 605 in the floor and ceiling of the slot 600 that function as rails. FIG. 7 shows a slot 700 with fixed partitions 705. FIG. 8 shows a slot 800 with fixed partitions 805 having integrated rails 810 that are captured in corresponding recesses 815 in an SSD 820. The partitions with rails may be used, for example, to locate the SSD within a slot that does not include a top surface or ceiling.

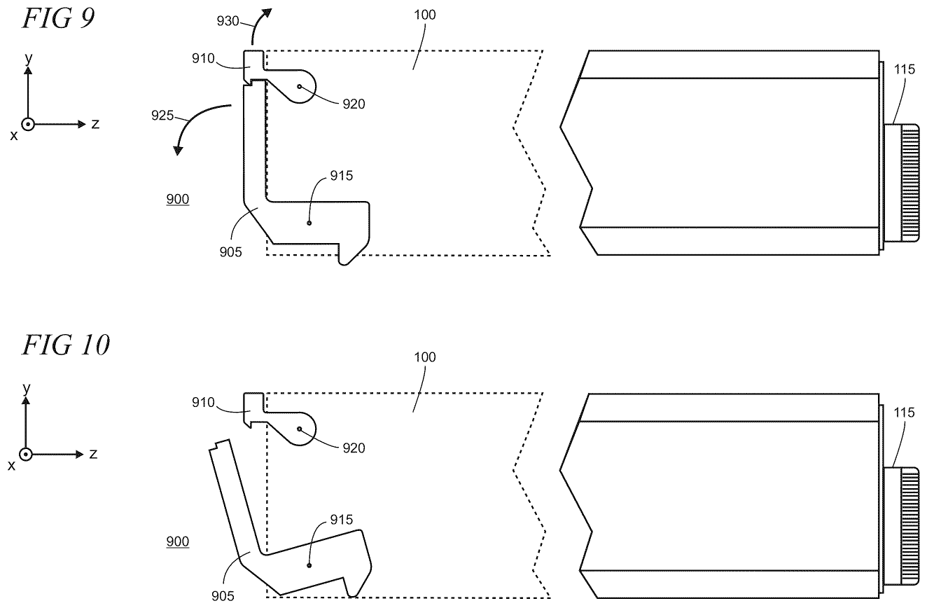

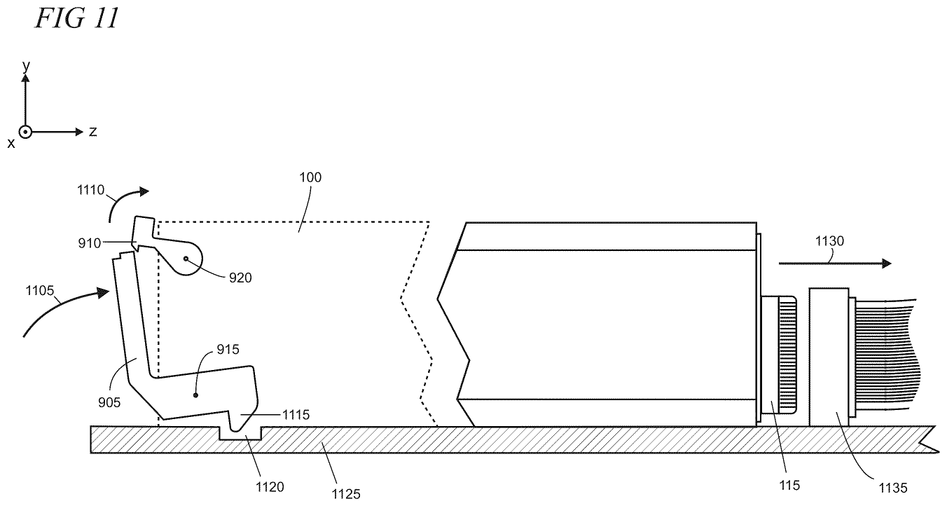

SSD 100 includes a latching mechanism 900 for installing the SSD in an electronic equipment rack as shown in the partially phantom views of the SSD in FIGS. 9-12 (it may be appreciated that the portions of the mechanism inside the dotted outline of the SSD are internally located within the SSD). The mechanism includes a finger-operable lever 905 and catch 910. The lever and catch are each rotatably mounted to pivot around respective pivots 915 and 920. The lever is spring-biased in the direction of rotation shown by arrow 925. The catch is spring-biased against the direction of rotation shown by arrow 930 (the springs are not shown in the drawing). Thus, when a user rotates the catch upwards (i.e., clockwise) against spring pressure, the spring bias of the lever causes it to rotate outwards (i.e., counter-clockwise). FIG. 10 shows the static resting positions of the lever and catch after the lever is released from the catch.

As shown in FIG. 11, when the user presses against the spring force on the lever to rotate the lever 905 in the direction of arrow 1105 (i.e., clockwise), the leading edge of the lever pushes against a beveled edge of the catch 910. The catch pivots upwards in the direction of arrow 1110 (i.e., clockwise) against the spring force. The rotation of the lever moves a pawl 1115 towards a mating feature 1120, such as a slot, recess, stop, ridge, or groove, in the floor 1125 of the rack. As the lever is rotated, the engagement of the pawl with the mating feature causes the SSD 100 to slide towards the right (i.e., in the “z” direction), as indicated by arrow 1130. With continued movement of the SSD, the connector 115 engages with a corresponding mating connector 1135 fixed to the rack.

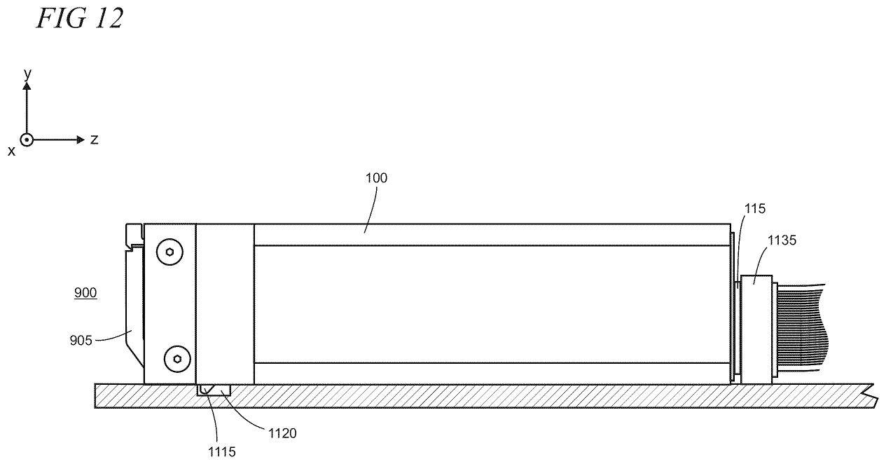

With continued rotational motion of the lever 905, the catch 910 will engage with a recessed area of the lever and hold it closed. FIG. 12 shows the mechanism 900 in the closed position with the lever 905 pushed against the SSD 100 in a vertical orientation. The pawl 1115 is fully extended into the mating feature 1120 to push the SSD into full registration in the space and ensure that the connectors 115 and 1135 are fully seated to provide a good electrical connection.

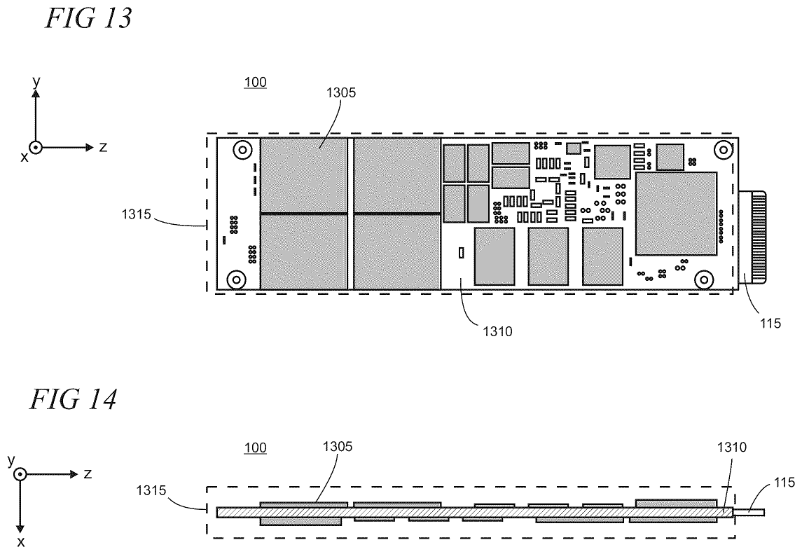

FIGS. 13 and 14 show respective side and top views of internal active components (representatively indicated by reference numeral 1305) of the SSD 100. The active components typically include, for example, NAND non-volatile flash memory, DRAM (dynamic random access memory), and controllers. The active components are mounted on a printed circuit board 1310. The active components, which produce heat when powered-up in an operating state, can be mounted on either or both sides of the printed circuit board.

The active components 1305, as in this illustrative example, can have different stand-off heights from the surface of the printed circuit board 1310. In addition, the components may have different heat outputs. The varying heights can cause difficulty to provide good thermal contact between them and a flat and rigid case (indicated by the dashed line 1315). The different active component size is typically dealt with by the use of thick thermal gap pads. While effective in some applications, the gap pads, case, and air-cooling fins are space-consuming and can make the SSD relatively thick (i.e., in the “x” direction). The thickness is increased even further in SSD designs in which air-cooling fins are utilized on both sides. It may be appreciated that increasing SSD thickness results in less SSD packing density which is generally undesirable for datacenter operators.

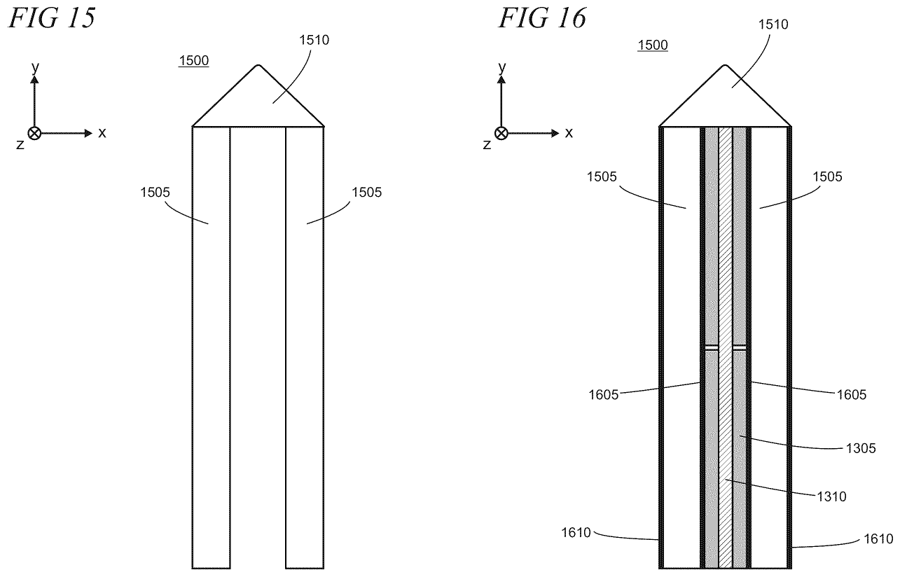

FIG. 15 is a front view of an illustrative SSD heat spreader assembly 1500 arranged in accordance with the present principles that is arranged for interoperation with a coldplate and liquid-cooling system to thereby bring the thermal benefits of liquid-cooling to SSDs while reducing the disadvantages of air-cooling such as lower packing density.

The heat spreader assembly 1500 includes planar heat spreader plates 1505 that are thermally coupled with a heat spreader bar 1510 which provides2 the external surfaces that function as a thermal interface contacting the coldplate. The heat spreader assembly is typically fabricated from materials having high thermal conductivity such as copper, aluminum, or other suitable metallic, non-metallic, and/or composite materials. The heat spreader bar has a peaked shape, however the shape shown is illustrative and not intended to be limiting. Other shapes and form factors incorporating the present principles are usable to meet the needs of a particular implementation. As shown in FIGS. 18 and 19, the peaked shape forms a longitudinal rib 1805 that interfaces with a corresponding longitudinal recess in a mating coldplate, as discussed below.

Returning to FIG. 15, the heat spreader plates 1505 may be fabricated from solid materials, hollow materials, or a combination of both. In some implementations, one or both of the heat spreader plates comprise thin vapor chambers arranged for two-phase cooling using an enclosed working fluid. The interior of the vapor chamber is a capillary structure vacuum chamber. After the working fluid absorbs heat from the active components of the SSD, it will vaporize rapidly and flow to a cooling zone provided at the heat spreader bar 1510 with the coldplate. When the vapor exchanges heat with the coldplate, it will condense back to fluid and flow back to the heat zone adjacent to the active components.

The heat spreader bar 1510 functions as a thermal hub that is located at the top of the heat spreader plates. The location at the top helps to optimize heat transfer to the coldplate because the heat-saturated vapor flows upward to the colder condenser sections of the plates.

FIG. 16 is a front view of an illustrative heat spreader when assembled to the internal active components 1305 and printed circuit board 1310 of the SSD 100. TIM 1605 is used to enhance the thermal conductivity between the active components and the heat spreader plates 1505. A variety of different TIM types are usable for assembling the heat spreader with the active components including, but not limited to, compressible gap pads, viscous materials such as pastes, phase-change materials, or combinations thereof. The TIM may be specified to be partially or fully curable. For example, in some applications a viscous removable thermal paste may be utilized as the TIM, while in others, a thermosetting epoxy may be preferred. The use of epoxy generally results in a thinner bond line which can reduce overall SSD packaging thickness. However, this benefit typically needs to be weighed against possible reduction in rework-ability as the epoxy is commonly removable only with solvents and/or the application of heat.

TIM 1610 is optionally utilized on portions or all of the exterior broad area surfaces of the heat spreader plates 1505. For this application, the TIM is selected from various thermally conductive dry-contact materials including, for example and without limitation, films, tapes, pads, and/or foils which may be constructed from silicon, graphite, or phase-change materials. Dry-contact TIM is also optionally disposed (not shown) on the outwardly facing surfaces of the heat spreader bar 1510.

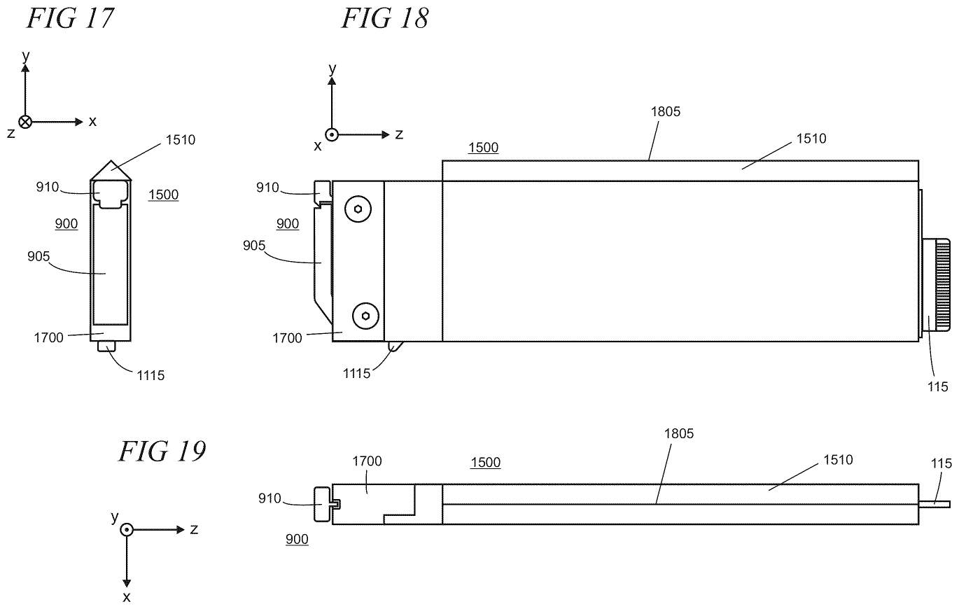

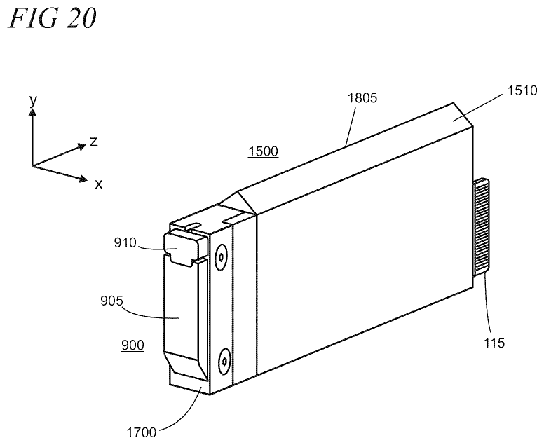

FIGS. 17-20 are pictorial front, side, top and three-quarter views of an SSD 1700 as adapted for liquid-cooling. As shown, the air-cooling fins are deleted and the heat spreader assembly 1500 replaces the case and gap pads used in the air-cooled SSD 100 shown in FIGS. 1-4. The heat spreader assembly thus provides some structural features to the SSD (e.g., providing appropriate rigidity to the SSD and protecting the internal components from environmental and/or handling damage) as well as thermal functionality. The latching mechanism 900 including the lever 905, catch 910, and pawl 1115 described above are adapted for use in the SSD 1700, as shown.

As discussed above, the active components of the SSD can have varying stand-off heights. In some implementations of the present principles, the heat spreader assembly is configurable to use multi-segment heat spreader plates to accommodate components of varying heights without having to utilize thick gap pads. Alternatively, a unitary (i.e., one-piece) heat spreader plate can be utilized to interface with the varying-height internal active components that are disposed on one side of the printed circuit board. In this embodiment, the inward-facing surfaces of a heat spreader plate (i.e., surfaces facing the components) are staggered with varying thicknesses while the outward-facing surfaces (i.e., externally exposed surfaces) of the plate are provided with a planar configuration.

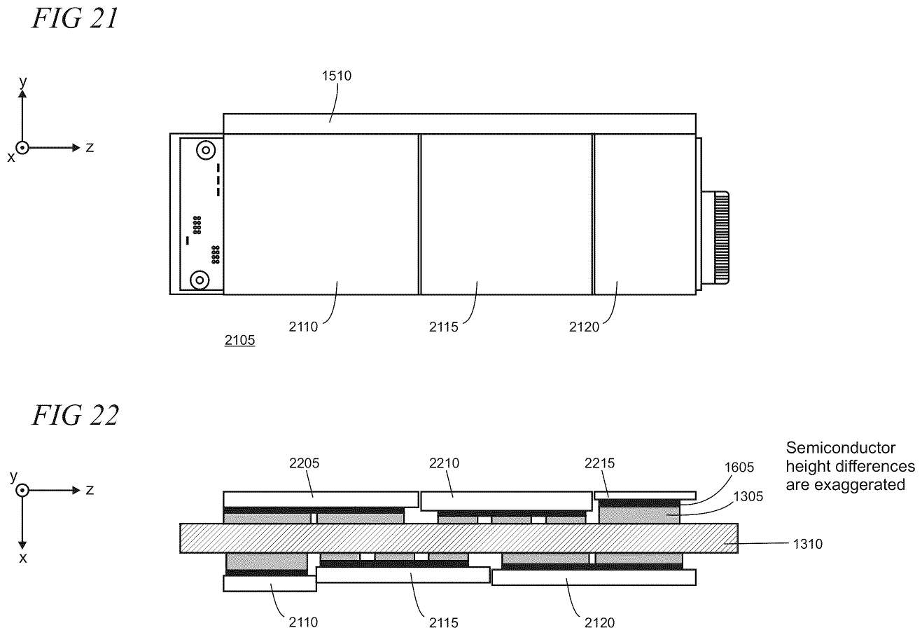

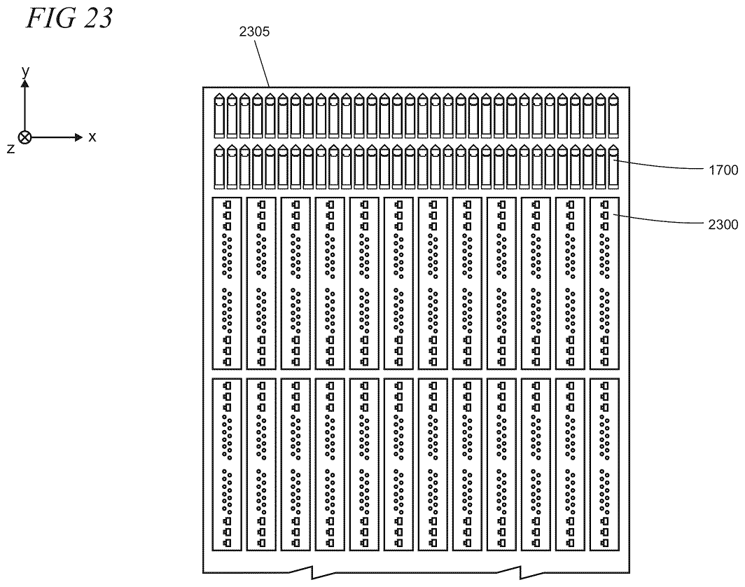

FIG. 21 shows a side view of an illustrative heat spreader assembly 2105 with multi-segment heat spreader plates 2110, 2115, and 2120 which are thermally coupled to a top-mounted heat spreader bar 1510. As shown in FIG. 22, the heat spreader plates 2110, 2115, and 2120 have a uniform thickness. On the opposite side, the heat spreader plates 2205, 2210, and 2215 have a non-uniform thickness (it is noted that the height differences among the active components is exaggerated for clarity in exposition).

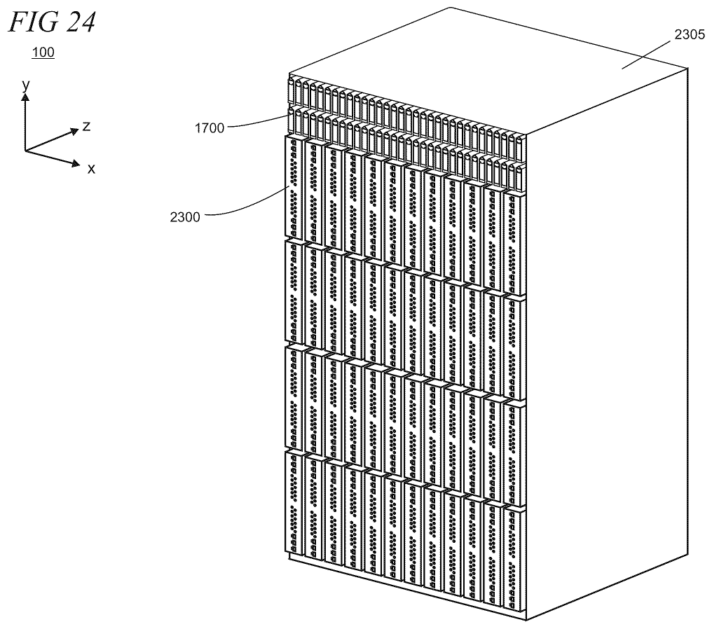

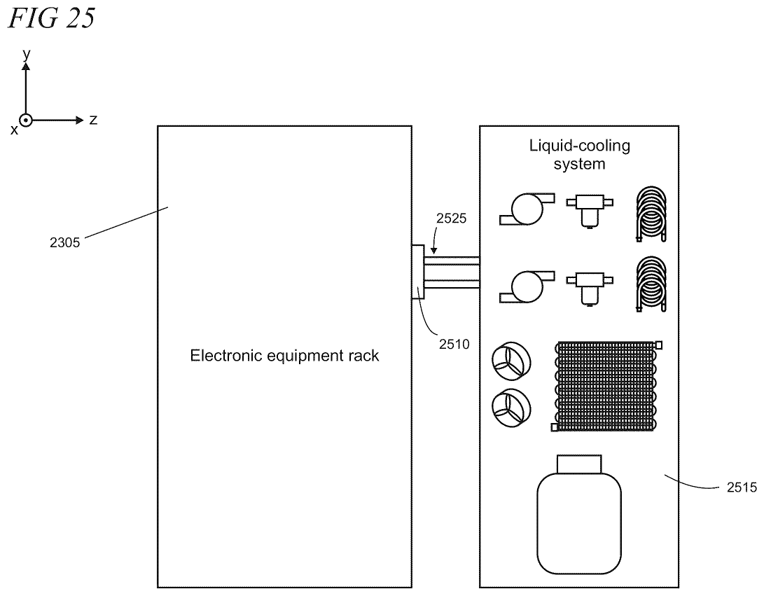

SSD 1700 may be utilized in datacenter applications in which liquid-cooling systems are adopted. FIGS. 23 and 24 show respective front and three-quarter views of an illustrative standard electronic equipment rack 2305 having rack-mounted SSDs 1700 and rack-mounted components such as computer servers 2300. FIG. 25 is a simplified schematic view of the electronic equipment rack 2305 having a liquid-cooling distribution system 2510 that interfaces with a liquid-cooling system 2515 via a fluid delivery system 2525. Other interfaces (not shown) such as those supporting control, monitoring, and alarm systems are also typically utilized between the equipment racks and the liquid-cooling system.

The liquid-cooling system 2515 includes various components that are utilized in common rack cooling scenarios in datacenters including, for example and without limitation, pumps, filters, hoses, fans, heat exchangers, fluid reservoirs, valves, controls, and the like. The liquid-cooling system is implementable as a standalone system or may be incorporated, in whole or part, into one or more equipment racks. The liquid-cooling distribution system 2510 is configured to provide liquid-cooling to individual rack-mounted components, including the SSDs and computer servers in this illustrative example.

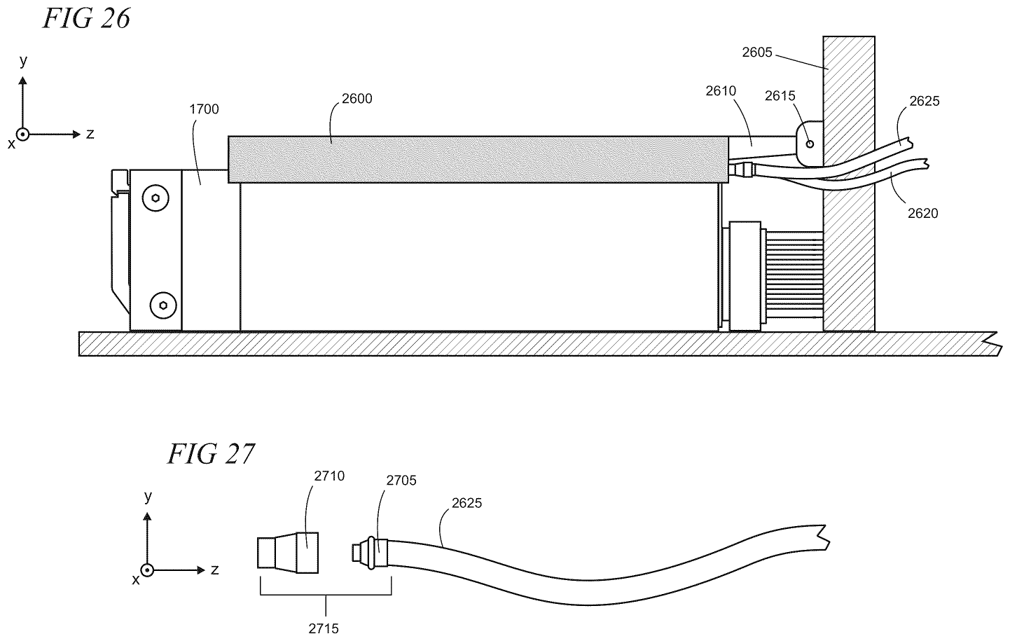

FIGS. 26 and 28 show respective side and three-quarter views of a first illustrative coldplate 2600 configured to provide liquid-cooling for an SSD 1700. The coldplate is moveably mounted in a slot that receives the SSD. In this illustrative example, the coldplate is hingedly mounted to a back wall 2605 of the SSD-receiving slot using a mounting arm 2610 and hinge 2615. The coldplate is coupled to the liquid-cooling distribution system 2510 (FIG. 25) in the rack using fluid delivery hoses 2620 and 2625.

The hoses are configurable as dry break hoses, as shown in FIG. 27 in which a coupler fitting 2705 on the hose 2620/2625 interfaces with a corresponding coupler 2710 on the coldplate. The dry break coupling 2715 is designed to be coupled and uncoupled without significant loss of coolant. In alternative implementations, the hoses are non-removably coupled to the coldplate which may increase reliability of the connection between the coldplate and liquid-cooling systems. For example, respective coupling components on the hoses and coldplate can be coupled via adhesives, welding, or other suitable coupling methodologies.

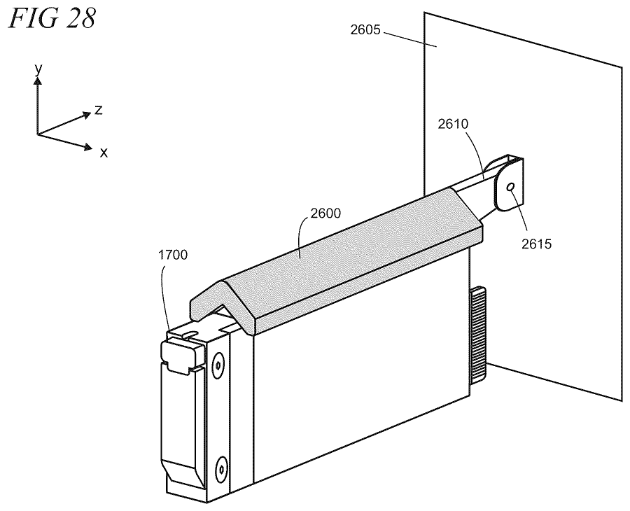

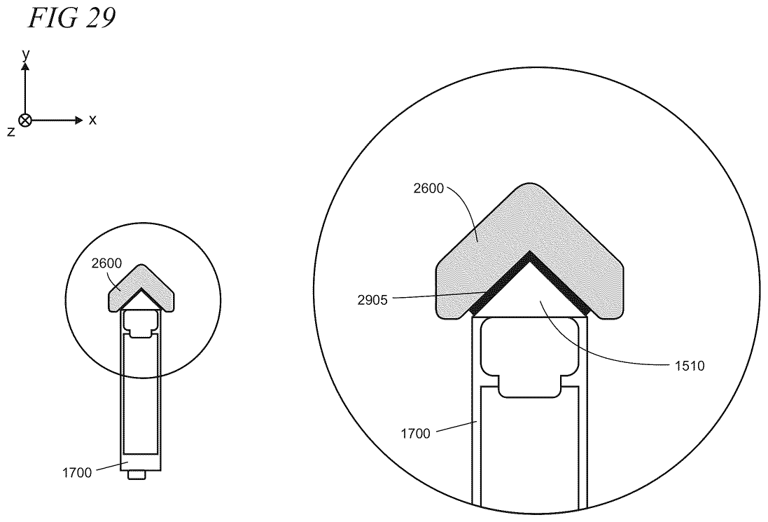

FIG. 29 shows front views of the coldplate 2600. As shown in the enlarged view, a dry-contact gap pad 2905 is mounted on an underside surface of the coldplate. The dry-contact gap pad is located between mating surfaces of the coldplate and the heat spreader bar 1510 when the coldplate comes into thermal contact with the SSD. It may be appreciated that a variety of diverse TIM types are adaptable for use as the dry-contact gap pad. In an illustrative embodiment, the dry-contact gap pad comprises a thermal gap filler pad such as a pad formed from an elastically compressible material which may include, for example, composites comprising elastomers with thermal fillers.

In another illustrative embodiment, the dry-contact gap pad 2905 comprises a viscous TIM that is held between layers of polymer film. The viscous TIM can be selected, for example and not by way of limitation, from one of phase change material, thermal grease, thermal paste, thermal putty, thermal gel, graphite-based material, silicone-based material, or metal-based material. The utilization of polymer film keeps the interface between mating heat spreader and coldplate components dry while still providing reasonable wetting characteristics and good thermal conductivity. The polymer film also acts as a wear surface as it comes into physical contact with the SSD heat spreader.

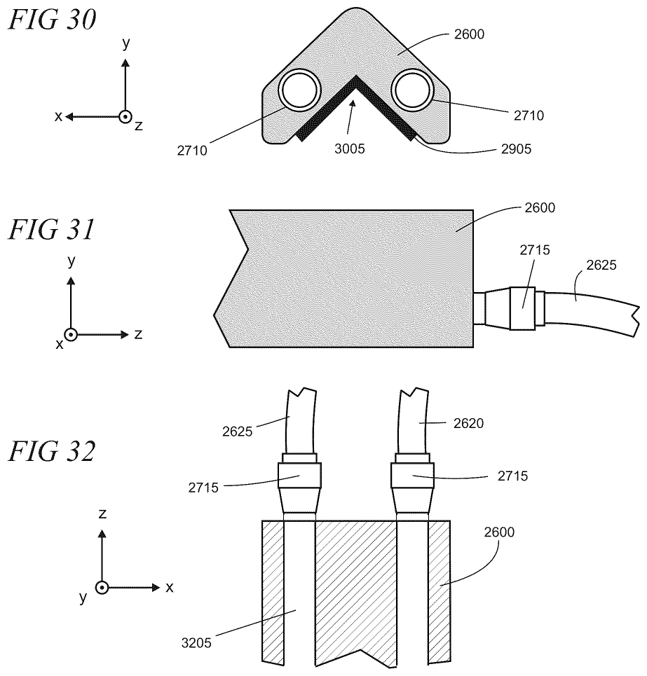

FIGS. 30-32 are detailed views of the coldplate 2600. The coldplate includes couplers 2710 for respective coolant input and output to internal passages 3205 of the coldplate when the fluid delivery hoses 2620 and 2625 are coupled using the dry break coupling 2715.

The coldplate can be fabricated from various thermally conductive materials such as copper, aluminum, or other suitable metallic, non-metallic, and/or composite materials. For example, the coldplate can be fabricated from billet copper and machined to form the correct outer shape using one or multiple subcomponents that are assembled using adhesives or fasteners and/or processes such as welding, etc. Internal passages can be formed using a suitable material removal process such as drilling or milling. Alternative fabrication processes comprise extrusion, metal casting, pressing, stamping, molding, etc. For example, the internal passages 3205 may be fabricated using copper tubing and assembled to an extruded shell that forms the contacting surfaces with an SSD.

The shape of the coldplate 2600 is peaked, as shown in the front view of FIG. 30. The peaked shape is illustrative and not intended to be limiting. Other shapes and form factors incorporating the present principles are usable to meet the needs of a particular implementation. The peaked coldplate shape provides increased surface area for thermal conduction from the SSD heat spreader compared with, for example, a flat planar surface. A longitudinal inversely-peaked internal recess 3005 is located on the underside of the coldplate. The recess interfaces with the corresponding rib 1805 (FIG. 18) of the heat spreader bar 1510. These corresponding features can help to maintain alignment and registration of the SSD 1700 as it slides into the slot in the rack 2305 (FIG. 23).

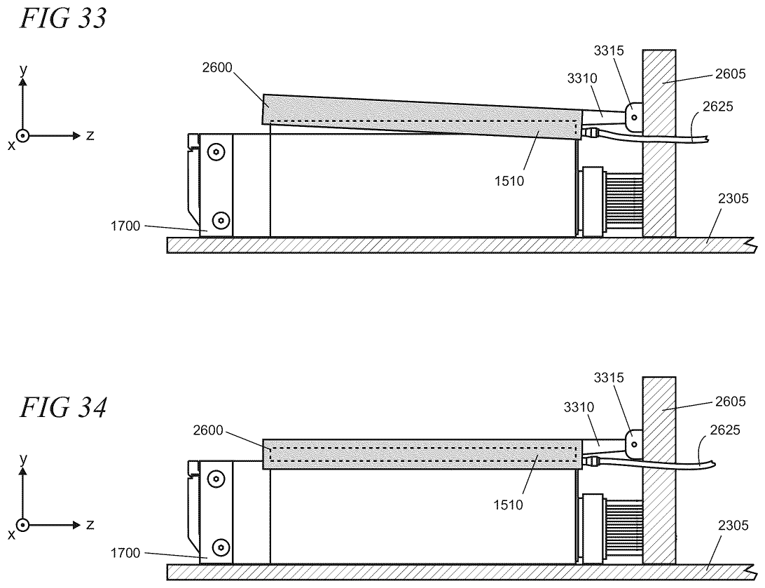

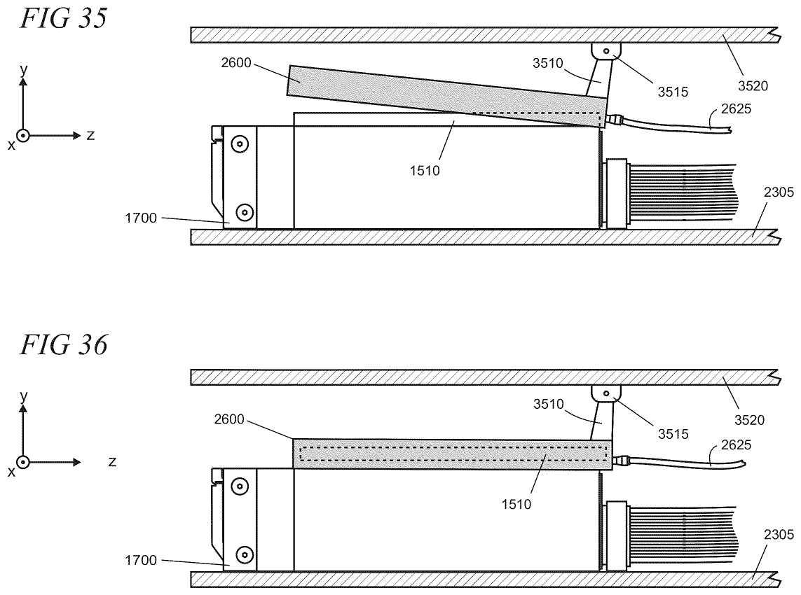

FIGS. 33-35 show respective side views of the coldplate 2600 that is hingedly mounted in the rack 2305 in open and closed positions. FIGS. 33 and 34 show a hinged mounting arm 3310 which is fixedly attached to a back wall 2605 of the SSD-receiving slot using a wall-mounted hinge 3315. In an alternative configuration, a hinged mounting arm 3510 is fixedly attached to a ceiling 3520 or top surface of the slot using a top-mounted hinge 3515, as shown in FIGS. 35 and 36. Use of hinged mounting enables movement of the coldplate relative to the SSD 1700 into different positions to facilitate easy installation of the SSD as it slides into its slot in the rack.

The range of movement of the coldplate 2600 can vary by application and is not required to match the ranges shown in the drawings which are illustrative. In some applications the range of movement and differences between coldplate positions before, during, and after SSD installation are relatively small. Generally, as the SSD slides into its slot during installation, the coldplate is first positioned (i.e., in an open position) to provide sufficient clearance to minimize sliding frictional forces between the coldplate and the heat spreader bar to facilitate ease of installation. Minimization of friction also reduces wear of the dry-contact gap pad 2905. When the SSD is seated in the slot, the coldplate hingedly rotates from the clearance position to a second position (i.e., to a closed position) providing zero clearance, or near-zero/minimal clearance, so that the coldplate and heat spreader bar are in intimate thermal contact to maximize heat transfer from the SSD to the liquid-cooling system.

In some embodiments, the hinge is spring-biased so that the static or resting position of the coldplate 2600 is in, or near, the non-clearance position prior to SSD installation. The spring biasing provides some downward (i.e., in the negative “y” direction) clamping pressure on the interface between the coldplate 2600 and the heat spreader bar 1510 when SSD 1700 is in its installed/seated position in the slot. Such downwardly-directed clamping force from the coldplate may enhance the quality of the thermal contact with the heat spreader bar.

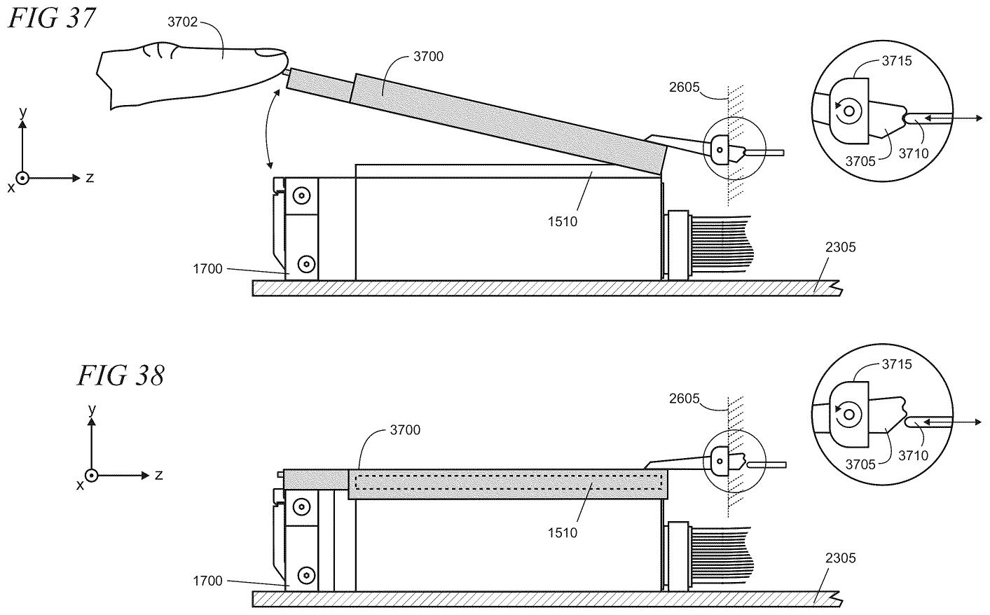

When a spring-biased mounting mechanism is used for the coldplate, as shown in FIGS. 37 and 38, an installation technician 3702 can manually move a coldplate 3700 into a clearance position and then slide the SSD 1700 into position in the rack slot. The coldplate may utilize a catch or other suitable mechanism to hold it in place in the clearance position against the spring force to facilitate one-handed SSD installation. Once the SSD is seated, the catch is released so that the spring force moves the coldplate into its non-clearance position to place it in thermal contact with the heat spreader bar 1510 of the SSD.

A catch 3705 uses a cammed surface that interfaces with moveable pin 3710 that is spring-biased to push the pin towards the catch. When the coldplate 3700 is moved into its open position by rotating about the hinge 3715, the pin pushes against the cam surface of the catch to hold the coldplate up against the torque provided (in a counter-clockwise direction in the drawing) from a biasing spring (not shown) in the hinge. After the SSD is seated, the technician rotates the coldplate 3700 downwards to force the pin off the cam of the catch. Once the catch is released, the spring force from the hinge applies clamping pressure to the SSD heat spreader 1510 from the coldplate, as shown in FIG. 38.

In some embodiments, the coldplate 2600 is fixedly located within the rack slot in a non-clearance/closed position with respect to the SSD 1700, or in a position having minimal clearance, and is not configured for substantial movement. Alternatively, the coldplate is moveably mounted in the rack to provide slight movement of the coldplate, for example using mounting fixtures having some degree of flex. In both such cases, positive thermal contact between the coldplate and the heat spreader bar is maintained for the installed SSD. The dry-contact gap pad 2905 (FIG. 29) may be configured with increased thickness in some implementations in which a fixed-location coldplate is utilized.

Some frictional force at the interface between the heat spreader bar and coldplate can be expected as the surfaces slide past each other during SSD installation. The increased frictional forces manifested in static/non-moveable coldplate embodiments may cause some additional effort for the technician when installing the SSD. Friction between the coldplate and heat spreader bar can also increase wear of the dry-contact gap pad 2905 (FIG. 29) in some scenarios. However, the surface texture of the polymer film utilized in the dry-contact gap pad may be specified with low-friction surface characteristics to minimize the frictional effects.

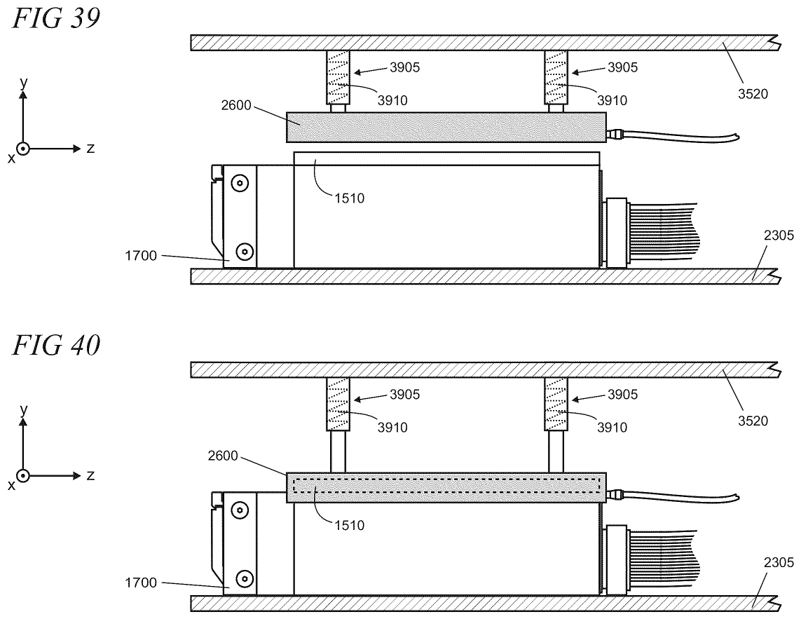

FIGS. 39 and 40 are side views of the coldplate 2600 that is mounted in the rack 2305 in respective open and closed positions. The coldplate mounting includes a mounting mechanism 3905 at the ceiling 3520 of the rack slot providing parallel movement of the coldplate relative to the SSD 1700. The types and construction of the parallel-movement mechanisms can vary by implementation. In this illustrative example, a telescopic mechanism is used having internal springs 3910 that are biased to provide a downward force (i.e., in the negative “y” direction). The mechanism provides clamping pressure from the coldplate on the SSD heat spreader bar 1510.

Other suitable parallel-movement mechanisms include, for example and without limitation, multi-bar mechanical linkages such as four-bar and six-bar linkages. The mechanisms can be spring-biased in some cases to put coldplate 2600 into a non-clearance/closed resting position.

The coldplate and SSD are configurable to use various different latching arrangements to facilitate the positioning of the coldplate during SSD installation. Such latching can further ensure establishment of positive thermal contact between the coldplate and the SSD heat spreader bar when the SSD is fully seated in position within its slot in the equipment rack 2305.

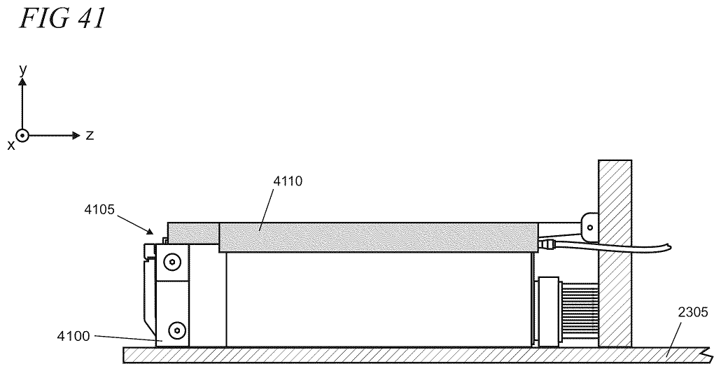

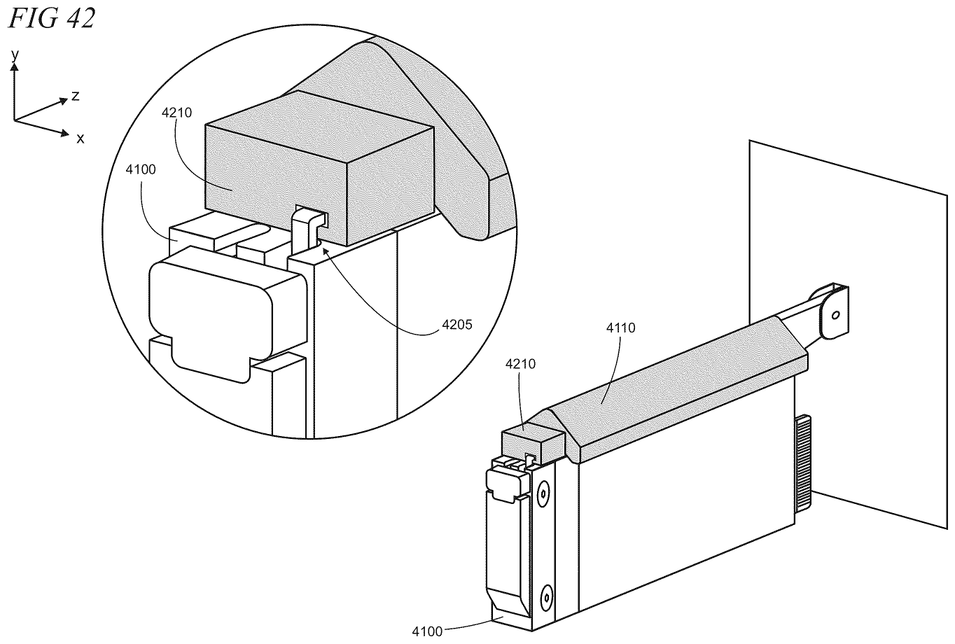

FIGS. 41 and 42 show respective side and three-quarter views of an illustrative SSD 4100 having a mechanism 4105 for latching and unlatching a hingedly-mounted coldplate 4110 to the SSD when installed in the rack 2305. The latching mechanism may be utilized, at least in part, to secure the SSD within the rack and also pull the coldplate into intimate thermal contact with the SSD heat spreader bar.

For a given SSD design, the latching mechanism may be implemented by itself or in combination with hinge springs, as discussed above, to provide clamping pressure on the interface between the heat spreader bar and coldplate when the SSD is seated in the slot. When the coldplate is in its non-clearance position relative to the mounted SSD, and lever 905 is in its closed position, a latch finger 4205 is extended into a latch finger receiver 4210 that is attached to the end of the coldplate, as shown in the enlarged view in FIG. 42.

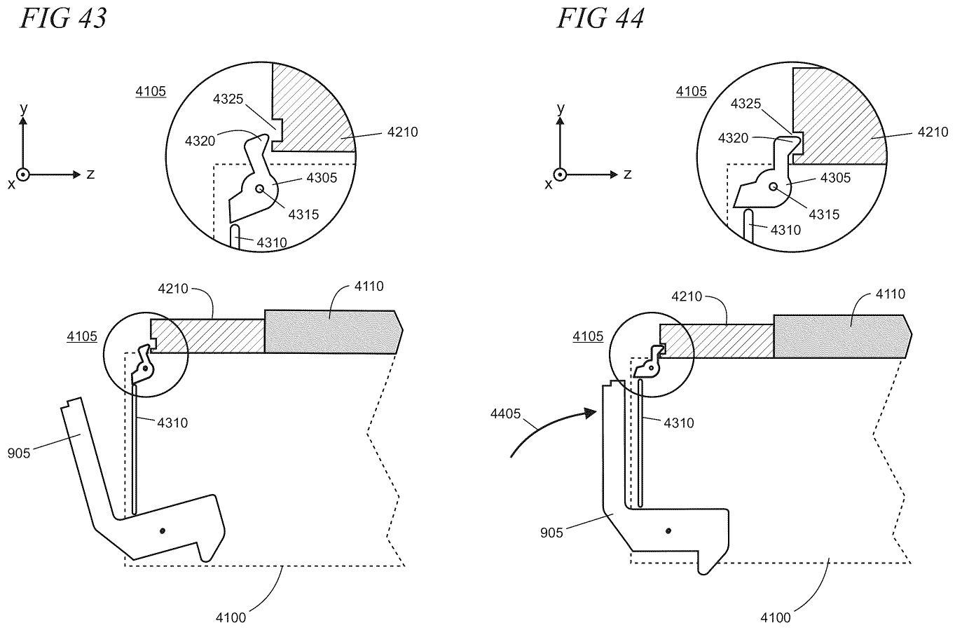

FIGS. 43 and 44 provide partially phantom views of portions of the SSD 4100 to show internal details of the latching mechanism 4105 that includes a finger 4305 and linkage 4310. The finger is rotatably mounted to pivot around a pivot 4315. The latch finger includes a wedge 4320 that engages with a slot 4325 in the receiver 4210. The profile of the wedge applies a downward force to the receiver as the latch finger is rotated about the pivot. The latch finger is operably connected to a proximal end of a linkage 4310, such as an internally-captured pushrod as shown, that is operably coupled at its distal end to the lever 905. The pivoting motion of the lever, as indicated by arrow 4405, applies a rotational torque to the finger through the linkage to force the wedge into the slot and draw the coldplate down (i.e., in a negative “y” direction) into intimate thermal contact with the heat spreader bar of the SSD.

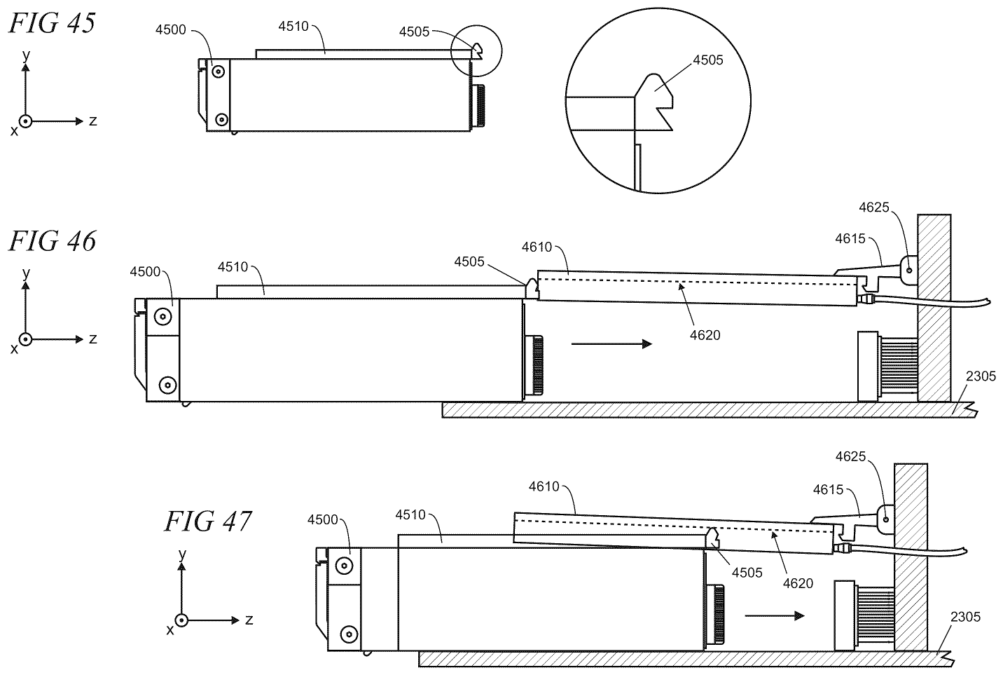

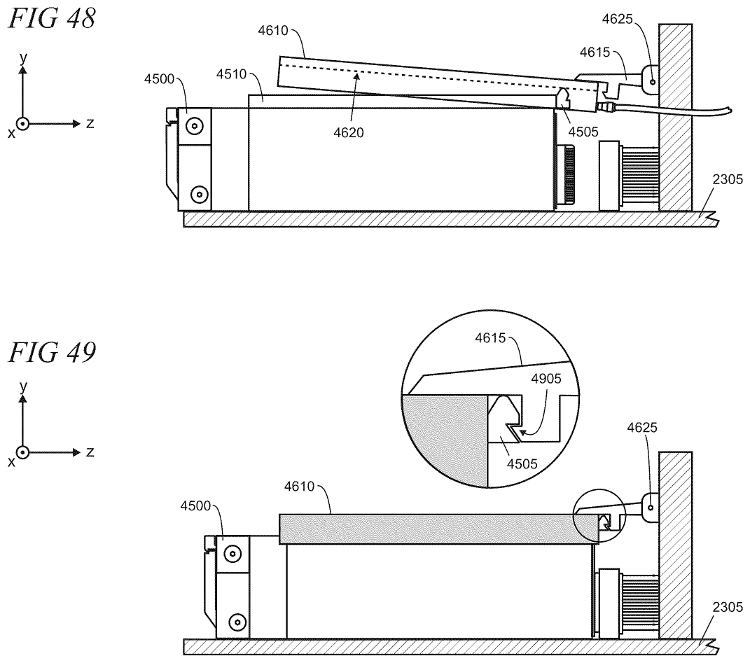

FIGS. 45-49 show another illustrative embodiment of a latching mechanism that may be utilized in some SSD applications. FIG. 45 is a side view of an illustrative SSD 4500 that includes a slotted cam 4505 disposed at the end of the heat spreader bar 4510 configured to slideably engage with a hingedly-mounted coldplate 4610 as the SSD is slideably installed in the rack 2305. As shown in FIG. 46, the coldplate includes a mounting arm 4615 having a wedge feature that pushes against a slot in the cam to latch the coldplate to the heat spreader bar as the SSD is seated in its slot in the rack.

As shown in the partially phantom views of the coldplate 4610 in FIGS. 46-48, the cam 4505 bears against surfaces of the internal recess on the underside of the coldplate (as indicated by the dashed line 4620) as the SSD 4500 is pushed into the rack 2305. The cam pushes the coldplate up against the spring force provided by biasing springs (not shown) included in a hinge 4625. This pushing motion places the coldplate into a clearance position to minimize friction and wear between the dry-contact gap pad (not shown) on the underside of the coldplate and the heat spreader bar 4510 during SSD installation.

When the SSD is fully seated in the rack 2305, as shown in FIG. 49, the cam 4505 clears the coldplate 4610 and engages with the wedge 4905 in the mounting arm 4615. The engagement of the cam's slot with the wedge operates to positively latch the coldplate to the SSD 4500. The downward force applied to the coldplate from the wedge may also provide some clamping pressure from the coldplate to enhance the thermal contact between the coldplate and the heat spreader bar on the SSD. The clamping pressure from the latching mechanism can supplement that provided by the biasing springs in the hinge 4625.

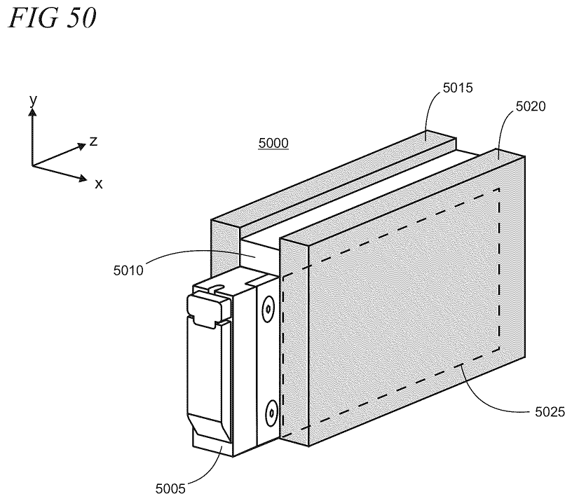

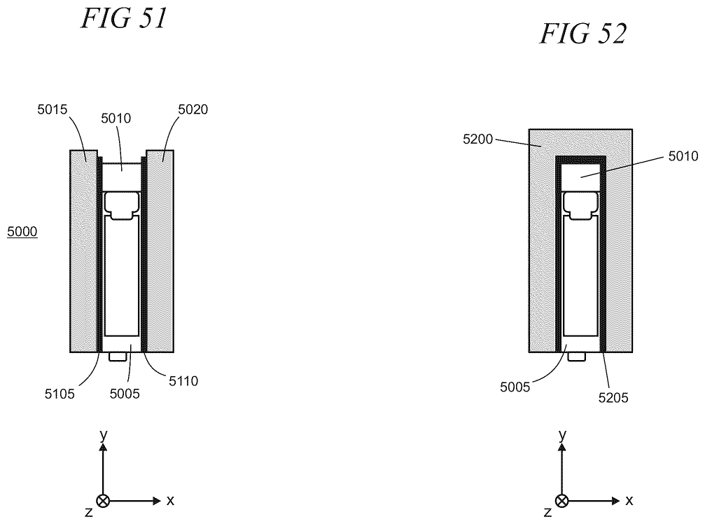

FIGS. 50 and 51 show respective three-quarter and front views of a second illustrative liquid-cooled coldplate 5000 that is double-sided and configured for use in an electronic equipment rack to provide liquid-cooling for an SSD 5005. The SSD 5005 is configurable in a similar manner as SSD 1700 (FIG. 17) except that the heat spreader bar 5010 is provided with a rectangular rather than a peaked profile.

The coldplate 5000 is embodied using two separate components 5015 and 5020 that are located on either side of the SSD to interface with the broad area surfaces of the heat spreaders in the SSD (the right-side heat spreader is indicated by the dashed line 5025) and the heat spreader bar 5010. Each component is liquid-cooled in a similar arrangement as with coldplate 2600 (FIG. 26) using suitable internal passages and couplers to fluid delivery hoses (not shown). Dry-contact gap pads 5105 and 5110 are disposed on the inward facing surfaces of the coldplate components to interface with the heat spreader assembly of the SSD, as shown in FIG. 51, when the SSD is mounted in the equipment rack.

The double-sided coldplate 5000 is alternatively mounted in the rack to enable hinged or parallel movement with respect to the SSD 5005 to facilitate SSD seating in the rack. In an alternative arrangement, the coldplate is fixedly-located in the rack. In this case, the dry-contact gap pads can be configured with increased thickness, and/or use a film layer with low-friction characteristics, to minimize sliding friction with the SSD during installation.

FIG. 52 shows an illustrative embodiment of a triple-sided coldplate 5200 that surrounds the SSD 5005 on its side and top surfaces. The triple-sided coldplate has increased surface area in contact with the heat spreader assembly in the SSD which can advantageously enhance heat transfer in some applications. The coldplate is liquid-cooled using suitable internal passages and couplers to fluid delivery hoses (not shown). A dry-contact gap pad 5205 is disposed on the inner surfaces of the coldplate, as shown.

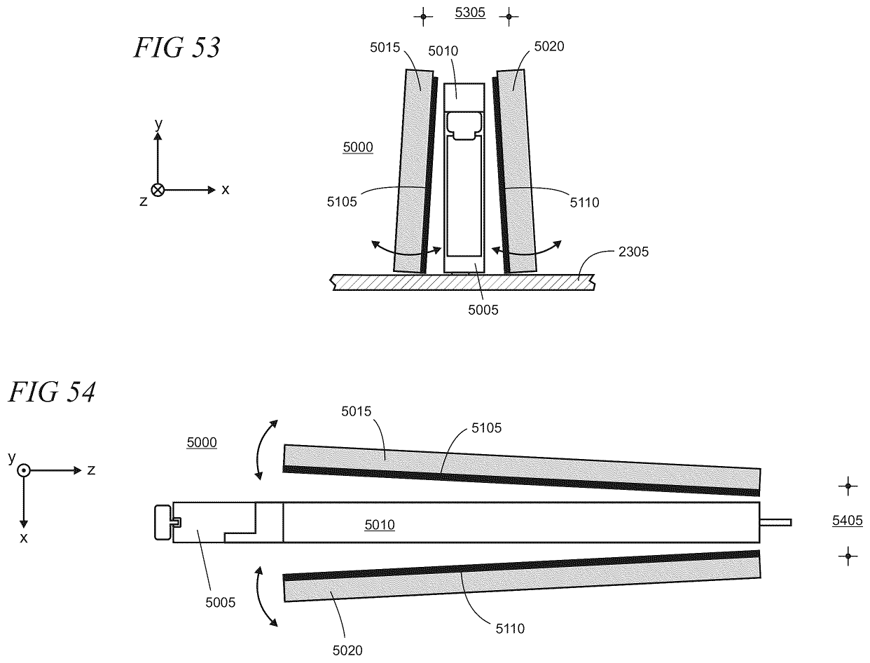

FIGS. 53 and 54 show respective front and top views of illustrative hinged movements of the double-sided coldplate 5000 with respect to the SSD 5005 during installation of the SSD in the rack 2305. The hinged movement is facilitated by suitable mounts and mechanisms (not shown) that can be similarly configured, for example, using one or more of the various arrangements shown and described above. Illustrative hinge points 5305 in FIG. 53 are implementable, for example, by a wall-mounted hinge in the rack. Illustrative hinge points 5405 in FIG. 54 are implementable, for example, by a ceiling-mounted hinge.

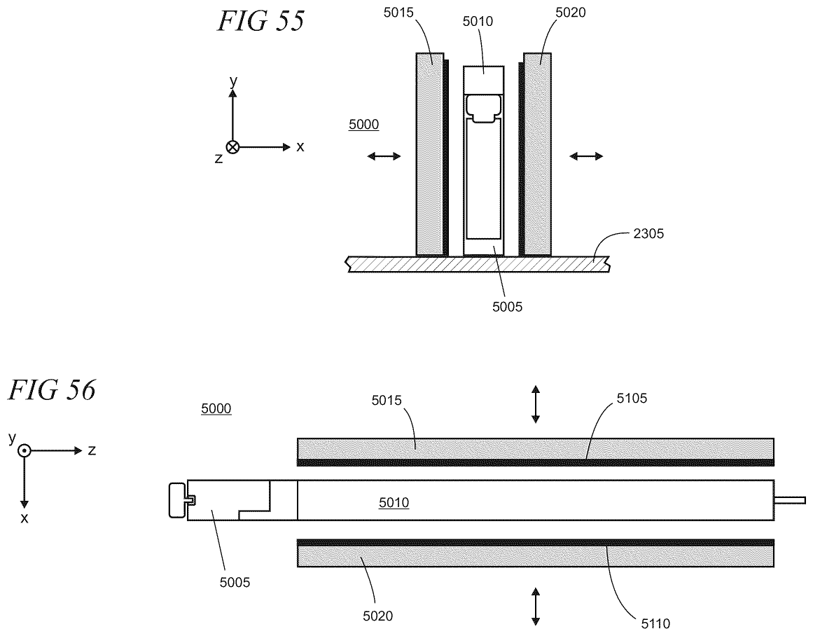

FIGS. 55 and 56 show respective front and top views of illustrative parallel movements of the double-sided coldplate 5000 with respect to the SSD 5005 during installation of the SSD in the rack 2305. The parallel movement is facilitated by suitable mounts and mechanisms (not shown) that can be similarly configured, for example, using one or more of the various arrangements shown and described above.

In alternative arrangements, one or both components 5015 and 5020 of the double-sided coldplate 5000 are fixedly-located within the rack 2305. The SSD 5005 is slideably installed in the rack past the fixed components of the coldplate. As with the first embodiment of the coldplate, the dry-contact gap pads are configurable to minimize sliding friction and wear, as discussed above.

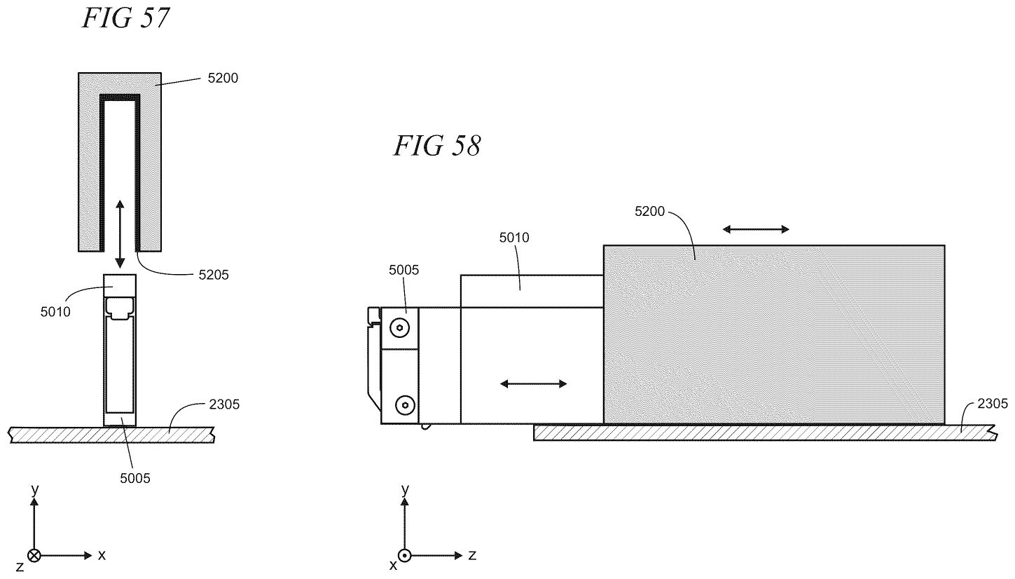

FIG. 57 shows illustrative up and down movements of the triple-sided coldplate 5200 that may be implemented, for example, using suitable mounts and mechanisms (not shown) for hinged and/or parallel movement of the coldplate with respect to the SSD 5005. The dry-contact gap pad 5205 is configured for slideable motion past the SSD heat spreader by having, for example, sufficient thickness and surface characteristics to minimize friction and/or wear.

FIG. 58 shows an illustrative arrangement in which either or both the triple-sided coldplate 5200 and SSD 5005 are slideable with respect to each other in a longitudinal direction. For example, the coldplate 5200 may be fixedly mounted in the rack 2305 and the SSD 5005 slides through the coldplate during installation. Alternatively, the coldplate may be moveably mounted in the rack using suitable mounts and mechanisms to longitudinally slide over the SSD as the SSD is installed in the rack or subsequently to the SSD being fully seated in the rack.

Various exemplary embodiments of the present hot-swappable liquid-cooled solid state drive are now presented by way of illustration and not as an exhaustive list of all embodiments. An example includes a liquid-cooling assembly providing liquid-cooling for a rack-mountable heat-producing electronic component, comprising: a rack providing receiving slots for each of a plurality of slideably removably mountable heat-producing electronic components, each of the electronic components having a heat spreader and one or more component-mounted connectors for power and data, the rack providing operating interfaces to each mounted electronic component via corresponding rack-mounted connectors for power and data, the rack further including a fluid distribution system having an interface to a liquid-cooling system; a liquid-cooled coldplate mounted in the rack, the coldplate having a component-contacting surface; and fluid couplers disposed on the coldplate connecting the coldplate to the fluid distribution system, wherein mounting of an electronic component in the rack comprises respective component-mounted and rack-mounted connectors being mechanically and electrically engaged to complete power and data circuits therethrough, and wherein the component-contacting surfaces of the coldplate are in intimate thermal contact with the heat spreader of the mounted electronic component to provide a thermal conduction path from the mounted electronic component to the liquid-cooling system.

In another example, the liquid-cooling assembly further comprises one or more dry-contact gap pads disposed on component-contacting surfaces of the coldplate. In another example, the dry-contact gap pad comprises a viscous thermal interface material (TIM) comprising one of phase change material, thermal grease, thermal paste, thermal putty, thermal gel, graphite-based material, silicone-based material, or metal-based material, in which the viscous TIM is captured by one or more layers of flexible polymer film. In another example, the fluid couplers comprise dry break fittings. In another example, the component-contacting surfaces of the coldplate are shaped to align the electronic component within a corresponding receiving slot of the rack. In another example, the coldplate is moveably mounted in the rack, the moveable mounting providing at least two positions for the coldplate in the rack, a first position of the coldplate providing spatial clearance between the component-contacting surfaces of the coldplate and the heat spreader of the electronic component during slidable motion of the electronic component in a corresponding receiving slot of the rack to effectuate mounting, and a second position of the coldplate providing intimate thermal contact of the component-contacting surfaces with the heat spreader of the electronic component when mounted. In another example, the coldplate is hingedly-mounted in the rack. In another example, the coldplate moves through the first and second positions based on motion of the electronic component in the receiving slot of the rack, such that the coldplate moves from the first position to the second position responsively to the electronic component being seated in the receiving slot and a respective component-mounted connector being electrically mated with a corresponding rack-mounted connector. In another example, the coldplate is spring-biased in the second position. In another example, the coldplate includes a linking mechanism that fixedly locates the coldplate to a predetermined location of the electronic component within the receiving slot of the rack. In another example, the electronic component comprises a solid state drive (SSD).

A further example includes a solid state drive (SSD) adapted for rack-mounting in an electronic equipment rack, in which the SSD is configured for slideable mounting within an SSD-receiving volume in the rack, the SSD comprising: a printed circuit board; a plurality of heat-producing semiconductors disposed on the printed circuit board, the semiconductors including NAND flash memory; a heat spreader, the heat spreader being in thermal contact with one or more of the heat-producing semiconductors, the heat spreader including an externally-facing thermal interface; a connector providing electrical connections to the printed circuit board and having a mateable portion for removable engagement with a corresponding rack-mounted connector; and a user-operable latching mechanism that is operable to apply force to an opposing surface in the rack to cause sliding motion of the SSD within the rack to seat the mateable portion of the connector with the rack-mounted connector to establish power and data circuits to the printed circuit board, wherein the thermal interface of the heat spreader provides a thermal conduction path for the heat-producing semiconductors to an external liquid-cooled coldplate that is disposed in the rack when the corresponding connectors of the SSD and rack are seated.

In another example, the SSD further comprises a thermal interface material (TIM) disposed between the heat-producing semiconductors and the heat spreader. In another example, the heat spreader comprises multiple discrete components, different components adapted to interface with heat-producing semiconductors having different stand-off heights with respect to the printed circuit board. In another example, the plurality of heat-producing semiconductors is disposed across both sides of the printed circuit board and the heat spreader comprises multiple components distributed on both sides of the printed circuit board over the heat-producing semiconductors. In another example, the heat spreader comprises a vapor chamber. In another example, the user-operable latching mechanism is further operable to releasably fasten the liquid-cooled coldplate to the SSD. In another example, the user-operable latching mechanism is operable to simultaneously seat the mateable portion of the connector with the rack-mounted connector and fasten the SSD to the liquid-cooled coldplate in one motion of the user-operable latching mechanism. In another example, the heat spreader encloses the printed circuit board and heat-producing semiconductors, and the SSD has a form factor for slideable motion relative to surfaces forming an SSD-receiving volume in the rack, wherein the form factor complies with specifications promulgated by the EDSFF (Enterprise and Datacenter Standard Form Factor).

A further example includes a liquid-cooling system, comprising: a liquid-cooled coldplate; a rack to which the coldplate is moveably mounted, the rack providing receiving slots for each of a plurality of slideably removably mountable solid state drives (SSD), each SSD comprising: a printed circuit board; a plurality of heat-producing semiconductors disposed on the printed circuit board, the semiconductors including NAND flash memory; a connector having a mateable portion for removable engagement with a corresponding rack-mounted connector, in which the mateable portion is exposed externally; a heat spreader, the heat spreader being in thermal contact with one or more of the heat-producing semiconductors, the heat spreader including a thermal interface that is at least partially externally exposed from the SSD; and a user-operable latching mechanism that is operable to apply force to the SSD-receiving slot to cause sliding motion of the SSD within the SSD-receiving slot to seat the mateable portion of the connector with the rack-mounted connector to establish power and data circuits to the printed circuit board, wherein the thermal interface of the heat spreader provides a thermal conduction path for the heat-producing semiconductors to the coldplate when the corresponding connectors of the SSD and rack are seated; a fluid distribution system having an interface to a liquid-cooling system; and fluid couplers disposed on the coldplate connecting the coldplate to the fluid distribution system.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed:

1. A liquid-cooling assembly providing liquid-cooling for a rack-mountable heat-producing electronic component, comprising:
a rack providing receiving slots for each of a plurality of slideably removably mountable heat-producing electronic components, each of the electronic components having a heat spreader and one or more component-mounted connectors for power and data, the rack providing operating interfaces to each mounted electronic component via corresponding rack-mounted connectors for power and data, the rack further including a fluid distribution system having an interface to a liquid-cooling system;
a liquid-cooled coldplate mounted in the rack, the coldplate having a component-contacting surface; and
fluid couplers disposed on the coldplate connecting the coldplate to the fluid distribution system,
wherein mounting of an electronic component in the rack comprises respective component-mounted and rack-mounted connectors being mechanically and electrically engaged to complete power and data circuits therethrough, and
wherein the component-contacting surfaces of the coldplate are in intimate thermal contact with the heat spreader of the mounted electronic component to provide a thermal conduction path from the mounted electronic component to the liquid-cooling system.

2. The liquid-cooling assembly of claim 1 further comprising one or more dry-contact gap pads disposed on component-contacting surfaces of the coldplate.

3. The liquid-cooling assembly of claim 2 in which the dry-contact gap pad comprises a viscous thermal interface material (TIM) comprising one of phase change material, thermal grease, thermal paste, thermal putty, thermal gel, graphite-based material, silicone-based material, or metal-based material, in which the viscous TIM is captured by one or more layers of flexible polymer film.

4. The liquid-cooling assembly of claim 1 in which the fluid couplers comprise dry break fittings.

5. The liquid-cooling assembly of claim 1 in which the component-contacting surfaces of the coldplate are shaped to align the electronic component within a corresponding receiving slot of the rack.

6. The liquid-cooling assembly of claim 1 in which the coldplate is moveably mounted in the rack, the moveable mounting providing at least two positions for the coldplate in the rack, a first position of the coldplate providing spatial clearance between the component-contacting surfaces of the coldplate and the heat spreader of the electronic component during slidable motion of the electronic component in a corresponding receiving slot of the rack to effectuate mounting, and a second position of the coldplate providing intimate thermal contact of the component-contacting surfaces with the heat spreader of the electronic component when mounted.

7. The liquid-cooling assembly of claim 6 in which the coldplate is hingedly-mounted in the rack.

8. The liquid-cooling assembly of claim 6 in which the coldplate moves through the first and second positions based on motion of the electronic component in the receiving slot of the rack, such that the coldplate moves from the first position to the second position responsively to the electronic component being seated in the receiving slot and a respective component-mounted connector being electrically mated with a corresponding rack-mounted connector.

9. The liquid-cooling assembly of claim 6 in which the coldplate is spring-biased in the second position.

10. The liquid-cooling assembly of claim 8 in which the coldplate includes a linking mechanism that fixedly locates the coldplate to a predetermined location of the electronic component within the receiving slot of the rack.

11. The liquid-cooling assembly of claim 1 in which the electronic component comprises a solid state drive (SSD).

12. A solid state drive (SSD) adapted for rack-mounting in an electronic equipment rack, in which the SSD is configured for slideable mounting within an SSD-receiving volume in the rack, the SSD comprising:
a printed circuit board;
a plurality of heat-producing semiconductors disposed on the printed circuit board, the semiconductors including NAND flash memory;
a heat spreader, the heat spreader being in thermal contact with one or more of the heat-producing semiconductors, the heat spreader including an externally-facing thermal interface;
a connector providing electrical connections to the printed circuit board and having a mateable portion for removable engagement with a corresponding rack-mounted connector; and
a user-operable latching mechanism that is operable to apply force to an opposing surface in the rack to cause sliding motion of the SSD within the rack to seat the mateable portion of the connector with the rack-mounted connector to establish power and data circuits to the printed circuit board,
wherein the thermal interface of the heat spreader provides a thermal conduction path for the heat-producing semiconductors to an external liquid-cooled coldplate that is disposed in the rack when the corresponding connectors of the SSD and rack are seated.

13. The SSD of claim 12 further comprising a thermal interface material (TIM) disposed between the heat-producing semiconductors and the heat spreader.

14. The SSD of claim 12 in which the heat spreader comprises multiple discrete components, different components adapted to interface with heat-producing semiconductors having different stand-off heights with respect to the printed circuit board.

15. The SSD of claim 12 in which the plurality of heat-producing semiconductors is disposed across both sides of the printed circuit board and the heat spreader comprises multiple components distributed on both sides of the printed circuit board over the heat-producing semiconductors.

16. The SSD of claim 12 in which the heat spreader comprises a vapor chamber.

17. The SSD of claim 12 in which the user-operable latching mechanism is further operable to releasably fasten the liquid-cooled coldplate to the SSD.

18. The SSD of claim 17 in which the user-operable latching mechanism is operable to simultaneously seat the mateable portion of the connector with the rack-mounted connector and fasten the SSD to the liquid-cooled coldplate in one motion of the user-operable latching mechanism.

19. The SSD of claim 12 in which the heat spreader encloses the printed circuit board and heat-producing semiconductors, and in which the SSD has a form factor for slideable motion relative to surfaces forming an SSD-receiving volume in the rack, wherein the form factor complies with specifications promulgated by the EDSFF (Enterprise and Datacenter Standard Form Factor).

20. A liquid-cooling system, comprising:
a liquid-cooled coldplate;
a rack to which the coldplate is moveably mounted, the rack providing receiving slots for each of a plurality of slideably removably mountable solid state drives (SSD), each SSD comprising:
a printed circuit board;
a plurality of heat-producing semiconductors disposed on the printed circuit board, the semiconductors including NAND flash memory;
a connector having a mateable portion for removable engagement with a corresponding rack-mounted connector, in which the mateable portion is exposed externally;
a heat spreader, the heat spreader being in thermal contact with one or more of the heat-producing semiconductors, the heat spreader including a thermal interface that is at least partially externally exposed from the SSD; and
a user-operable latching mechanism that is operable to apply force to the SSD-receiving slot to cause sliding motion of the SSD within the SSD-receiving slot to seat the mateable portion of the connector with the rack-mounted connector to establish power and data circuits to the printed circuit board,
wherein the thermal interface of the heat spreader provides a thermal conduction path for the heat-producing semiconductors to the coldplate when the corresponding connectors of the SSD and rack are seated;
a fluid distribution system having an interface to a liquid-cooling system; and
fluid couplers disposed on the coldplate connecting the coldplate to the fluid distribution system.
